(19) United States
(12) Patent Application Publication
(10) Pub. No.: US 2024/0421259 A1
(43) Pub. Date: Dec. 19, 2024

(54) LIGHT EMITTING DEVICE

(71) Applicants: TOYODA GOSEI CO., LTD., Kiyosu-shi (JP); MEIJO UNIVERSITY, Nagoya-shi (JP)

(72) Inventors: Koji OKUNO, Kiyosu-shi (JP); Yoshiki SAITO, Kiyosu-shi (JP); Masaki OYA, Kiyosu-shi (JP); Kengo NAGATA, Kiyosu-shi (JP); Tetsuya TAKEUCHI, Nagoya-shi (JP); Satoshi KAMIYAMA, Nagoya-shi (JP); Motoaki IWAYA, Nagoya-shi (JP); Hisanori ISHIGURO, Nagoya-shi (JP); Rie IWATSUKI, Nagoya-shi (JP)

(21) Appl. No.: 18/742,415

(22) Filed: Jun. 13, 2024

(30) Foreign Application Priority Data
Jun. 16, 2023 (JP) 2023-099392

(51) Int. Cl. H01L 33/44; H01L 33/00; H01L 33/06; H01L 33/14; H01L 33/32; H01L 33/40; H01L 33/58

(52) U.S. Cl. CPC H01L 33/44; H01L 33/007; H01L 33/06; H01L 33/145; H01L 33/325; H01L 33/405; H01L 33/58; H01L 2933/0025

(57) ABSTRACT

A light emitting device includes: a flip-chip type light emitting element; a sealing portion; and a lens as defined herein, the light emitting element includes an n-type layer, an active layer, an electron blocking layer, a composition gradient layer, a p-type contact layer, and a p-side electrode as defined herein, and a thickness of the composition gradient layer is set such that light directed from the active layer toward the n-type layer and light directed from the active layer toward a side opposite to the n-type layer and then reflected by the p-side electrode toward the n-type layer strengthen each other in a direction perpendicular to a main surface of the light emitting element due to interference.

### CROSS-REFERENCE TO RELATED APPLICATION

This application is based on and claims priority under 35 USC 119 from Japanese Patent Application No. 2023-099392 filed on Jun. 16, 2023.

### TECHNICAL FIELD

The present invention relates to a light emitting device.

### BACKGROUND ART

The wavelength of the ultraviolet ray from a solid-state light emitting element using a Group III nitride semiconductor corresponds to a wavelength band in a range of about 210 nm to 400 nm. In particular, it is known that UVC (wavelength of 100 nm to 280 nm) can efficiently sterilize and eliminate bacteria, and there is an increasing demand for a Group III nitride semiconductor LED that emits ultraviolet light having an emission wavelength corresponding to that of UVC. The ultraviolet LED has a structure in which an AlN layer is formed on a sapphire substrate, and an n-type layer, a light emitting layer, and a p-type layer made of AlGaN are stacked on the AlN layer.

JP2004-119756A describes that a thickness of a semiconductor layer in a light emitting element satisfies n×d=m×λ/2, in which n is the refractive index of the semiconductor layer, d is the thickness of the semiconductor layer, λ is the emission wavelength, and m is an integer. It is described that by setting the thickness of the semiconductor layer as described above, weakening due to interference of light inside the device can be prevented, and the light extraction efficiency can be improved.

JP2019-16964A describes that a composition gradient layer is provided between an electron blocking layer and a p-type contact layer. The composition gradient layer is made of AlN or AlGaN, and is configured such that the Al composition decreases as a distance from the electron blocking layer increases, and at an interface with the electron blocking layer, the Al composition is the same as that of the electron blocking layer. It is described that by providing the composition gradient layer, the generation of a two-dimensional hole gas is reduced and the generation of current crowding is reduced.

JP2022-108692A describes a light emitting device in which an ultraviolet LED mounted on a mounting substrate is covered with a lens, and a gap between the ultraviolet LED and the lens is filled with a liquid fluorocarbon compound.

### SUMMARY OF INVENTION

However, JP2004-119756A, JP2019-16964A and JP2022-108692A do not mention the angle dependency of light (light distribution) extracted from the light emitting element. For example, light extracted in a lateral direction of the light emitting element (a direction parallel to a main surface of the light emitting element) is difficult to be utilized in an actual product. Therefore, it is required to increase the axial intensity (light intensity in a direction perpendicular to the main surface of the light emitting element) in an internal structure of the element. In the method of JP2004-119756A, since a series resistance changes depending on the thickness of the semiconductor layer, there is a possibility that a drive voltage also changes.

The present invention has been made in view of such a background, and an object of the present invention is to provide a light emitting device capable of increasing axial intensity while suppressing an increase in drive voltage.

An aspect of the present invention is directed to a light emitting device comprising:
a flip-chip type light emitting element configured to emit ultraviolet light;
a sealing portion in contact with and covering at least an upper surface of the light emitting element and having a refractive index higher than a refractive index of air and lower than a refractive index of the light emitting element; and
a lens in contact with and covering the sealing portion and having a refractive index higher than the refractive index of the sealing portion,
wherein the light emitting element comprises
an n-type layer comprising an n-type group III nitride semiconductor containing Al,
an active layer located at a main surface of the n-type layer at a side opposite to the sealing portion, comprising a group III nitride semiconductor containing Al, and having a quantum well structure including a well layer and a barrier layer,
an electron blocking layer located at a main surface of the active layer at a side opposite to the n-type layer, comprising a p-type group III nitride semiconductor containing Al, and having an Al composition higher than an Al composition of the barrier layer,
a composition gradient layer located at a main surface of the electron blocking layer at a side opposite to the active layer, comprising a p-type group III nitride semiconductor containing Al, and having an Al composition which decreases as a distance from the active layer increases,
a p-type contact layer located at a main surface of the composition gradient layer at a side opposite to the electron blocking layer, and comprising a p-type group III nitride semiconductor containing Al, and
a p-side electrode located at a main surface of the p-type contact layer at a side opposite to the composition gradient layer, and configured to reflect ultraviolet light from the active layer, and
wherein a thickness of the composition gradient layer is set such that light directed from the active layer toward the n-type layer and light directed from the active layer toward a side opposite to the n-type layer and then reflected by the p-side electrode toward the n-type layer strengthen each other in a direction perpendicular to a main surface of the light emitting element due to interference.

An another aspect of the present invention is directed to a manufacturing method for a light emitting device,
the light emitting device including
a flip-chip type light emitting element configured to emit ultraviolet light,
a sealing portion in contact with and covering at least an upper surface of the light emitting element and having a refractive index higher than a refractive index of air and lower than a refractive index of the light emitting element, and
a lens in contact with and covering the sealing portion and having a refractive index higher than the refractive index of the sealing portion,
the light emitting element including
an n-type layer comprising an n-type group III nitride semiconductor containing Al,
an active layer located at a main surface of the n-type layer at a side opposite to the sealing portion, comprising a group III nitride semiconductor containing Al, and having a quantum well structure including a well layer and a barrier layer,
an electron blocking layer located oat a main surface of the active layer at a side opposite to the n-type layer, comprising a p-type group III nitride semiconductor containing Al, and having an Al composition higher than an Al composition of the barrier layer,
a composition gradient layer located at a main surface of the electron blocking layer at a side opposite to the active layer, comprising a p-type group III nitride semiconductor containing Al, and having an Al composition which decreases as a distance from the active layer increases,
a p-type contact layer located at a main surface of the composition gradient layer at a side opposite to the electron blocking layer, and comprising a p-type group III nitride semiconductor containing Al, and
a p-side electrode located at a main surface of the p-type contact layer at a side opposite to the composition gradient layer, and configured to reflect ultraviolet light from the active layer,
the manufacturing method comprising:
setting a thickness of the composition gradient layer such that light directed from the active layer toward the n-type layer and light directed from the active layer toward a side opposite to the n-type layer and then reflected by the p-side electrode toward the n-type layer strengthen each other in a direction perpendicular to a main surface of the light emitting element due to interference.

In the above aspects, the interference of ultraviolet light is controlled by the thickness of the composition gradient layer. Therefore, the axial intensity can be increased while suppressing an increase in drive voltage.

### BRIEF DESCRIPTION OF DRAWINGS

FIG. 1 is a cross-sectional view schematically showing a configuration of a light emitting device according to a first embodiment, and is a view showing a cross section perpendicular to a main surface of a light emitting element.

FIG. 2 is a cross-sectional view showing a configuration of the light emitting element, and is a view showing a cross section perpendicular to the main surface of the light emitting element.

FIG. 3A is a diagram schematically showing a path of light inside a model in which AlN, sapphire, air, and a lens (quartz) are stacked in order from an active layer side on an active layer, and FIG. 3B is a diagram schematically showing a path of light inside a model in which AlN, sapphire, fluorine oil, and a lens (quartz) are stacked in order from the active layer side on the active layer.

FIG. 4A is a graph showing angle dependency of light output for a simplified model of the light emitting element, and FIG. 4B is a graph showing thickness dependency of a p-type layer for a simplified model of the light emitting element.

FIG. 5 is a graph showing calculation results and measurement results of light output of the light emitting element.

FIG. 6 is a graph showing results of measuring light output of a light emitting device in which a light emitting element is packaged.

FIG. 7 is a graph showing measurement results of a rate of increase in axial intensity and a width of a radiation angle for the light emitting device in which the light emitting element is packaged.

FIGS. 8A and 8B are graphs showing results of calculating light output from an upper surface and light output from a side surface of the light emitting element.

FIG. 9A is a diagram showing a band diagram and a carrier concentration distribution in a thickness direction of the light emitting element when no voltage is applied, and FIG. 9B is a diagram showing the band diagram and the carrier concentration distribution in the thickness direction of the light emitting element when 6 V is applied.

FIG. 10 is a graph showing transmittance, absorptance, and reflectance of sapphire.

FIG. 11 is a graph showing transmittance, absorptance, and reflectance of an AlN template.

FIG. 12 is a graph showing transmittance, absorptance, and reflectance of the entire region from a substrate to a p-type contact layer.

FIG. 13 is a graph showing transmittance, absorptance, and reflectance of non-doped AlGaN.

FIG. 14 is a graph showing transmittance, absorptance, and reflectance of Si-doped AlGaN.

FIG. 15 is a graph showing transmittance, absorptance, and reflectance of Mg-doped AlGaN.

FIG. 16 is a graph showing transmittance, absorptance, and reflectance of a composition gradient layer.

FIG. 17 is a graph showing reflectance of a p-side electrode.

FIG. 18 is a cross-sectional view schematically showing a configuration of a light emitting device according to a modification of the first embodiment, and is a view showing a cross section perpendicular to a main surface of a light emitting element.

### DETAILED DESCRIPTION OF THE INVENTION

A light emitting device includes a flip-chip type light emitting element configured to emit ultraviolet light, a sealing portion in contact with and covering at least an upper surface of the light emitting element and having a refractive index higher than that of air and lower than that of the light emitting element, and a lens in contact with and covering the sealing portion and having a refractive index higher than that of the sealing portion.

The light emitting element includes: an n-type layer made of an n-type group III nitride semiconductor containing Al; an active layer located on a main surface of the n-type layer on a side opposite to the sealing portion, made of a group III nitride semiconductor containing Al, and having a quantum well structure including a well layer and a barrier layer; an electron blocking layer located on a main surface of the active layer on a side opposite to the n-type layer, made of a p-type group III nitride semiconductor containing Al, and having an Al composition higher than that of the barrier layer; a composition gradient layer located on a main surface of the electron blocking layer on a side opposite to the active layer, made of a p-type group III nitride semiconductor containing Al, and whose Al composition decreases as a distance from the active layer increases; a p-type contact layer located on a main surface of the composition gradient layer on a side opposite to the electron blocking layer, and made of a p-type group III nitride semiconductor containing Al; and a p-side electrode located on a main surface of the p-type contact layer on a side opposite to the composition gradient layer, and configured to reflect ultraviolet light from the active layer.

Further, a thickness of the composition gradient layer is set such that light directed from the active layer toward the n-type layer and light directed from the active layer toward the side opposite to the n-type layer and then reflected by the p-side electrode toward the n-type layer strengthen each other in a direction perpendicular to a main surface of the light emitting element due to interference.

In the light emitting device, when a total film thickness from an uppermost layer of the barrier layer to the p-type contact layer is d1, and the thickness of the composition gradient layer is d2, the thickness d2 may be set such that d1 satisfies n×d1=m×λ (where n is an average refractive index of layers from the electron blocking layer to the p-type contact layer at an emission wavelength, and λ is the emission wavelength), m being 0.55 or more and 0.9 or less.

The composition gradient layer may have a structure in which a first composition gradient layer and a second composition gradient layer are stacked in order from an electron blocking layer side, the first composition gradient layer is non-doped or doped with p-type impurities, and the second composition gradient layer is doped with p-type impurities and has a p-type impurity concentration higher than the first composition gradient layer.

The thickness of the composition gradient layer may be set by a thickness of the first composition gradient layer.

A ratio of a thickness of the first composition gradient layer to the thickness d2 of the composition gradient layer may be 0.4 to 0.7.

The sealing portion may be provided on the upper surface of the light emitting element and may not be provided on a side surface of the light emitting element.

The electron blocking layer may have a structure in which a first electron blocking layer and a second electron blocking layer are stacked in order from an active layer side, and an Al composition of the second electron blocking layer is lower than an Al composition of the first electron blocking layer and lower than a maximum value of the Al composition of the composition gradient layer.

A manufacturing method for a light emitting device, the light emitting device includes a flip-chip type light emitting element configured to emit ultraviolet light, a sealing portion in contact with and covering at least an upper surface of the light emitting element and having a refractive index higher than that of air and lower than that of the light emitting element, and a lens in contact with and covering the sealing portion and having a refractive index higher than that of the sealing portion. The light emitting element includes: an n-type layer made of an n-type group III nitride semiconductor containing Al; an active layer located on a main surface of the n-type layer on a side opposite to the sealing portion, made of a group III nitride semiconductor containing Al, and having a quantum well structure including a well layer and a barrier layer; an electron blocking layer located on a main surface of the active layer on a side opposite to the n-type layer, made of a p-type group III nitride semiconductor containing Al, and having an Al composition higher than that of the barrier layer; a composition gradient layer located on a main surface of the electron blocking layer on a side opposite to the active layer, made of a p-type group III nitride semiconductor containing Al, and whose Al composition decreases as a distance from the active layer increases; a p-type contact layer located on a main surface of the composition gradient layer on a side opposite to the electron blocking layer, and made of a p-type group III nitride semiconductor containing Al; and a p-side electrode located on a main surface of the p-type contact layer on a side opposite to the composition gradient layer, and configured to reflect ultraviolet light from the active layer. A thickness of the composition gradient layer is set such that light directed from the active layer toward the n-type layer and light directed from the active layer toward the side opposite to the n-type layer and then reflected by the p-side electrode toward the n-type layer strengthen each other in a direction perpendicular to a main surface of the light emitting element due to interference.

When a total film thickness from an uppermost layer of the barrier layer to the p-type contact layer is d1, the thickness of the composition gradient layer is d2, and d3=d1-d2, by changing the thickness d2 while fixing the thickness d3 to a predetermined value, the thickness d2 may be set such that n×d1=m×λ (where n is an average refractive index of layers from the electron blocking layer to the p-type contact layer at an emission wavelength, and A is the emission wavelength) is satisfied, m being 0.55 or more and 0.9 or less.

The composition gradient layer may have a structure in which a first composition gradient layer and a second composition gradient layer are stacked in order from an electron blocking layer side, the first composition gradient layer is non-doped or doped with p-type impurities, and the second composition gradient layer is doped with p-type impurities and has a p-type impurity concentration higher than the first composition gradient layer. The thickness of the composition gradient layer may be set by fixing a thickness of the second composition gradient layer to a predetermined value and changing a thickness of the first composition gradient layer.

### Embodiments

### 1. Configuration of Light Emitting Device

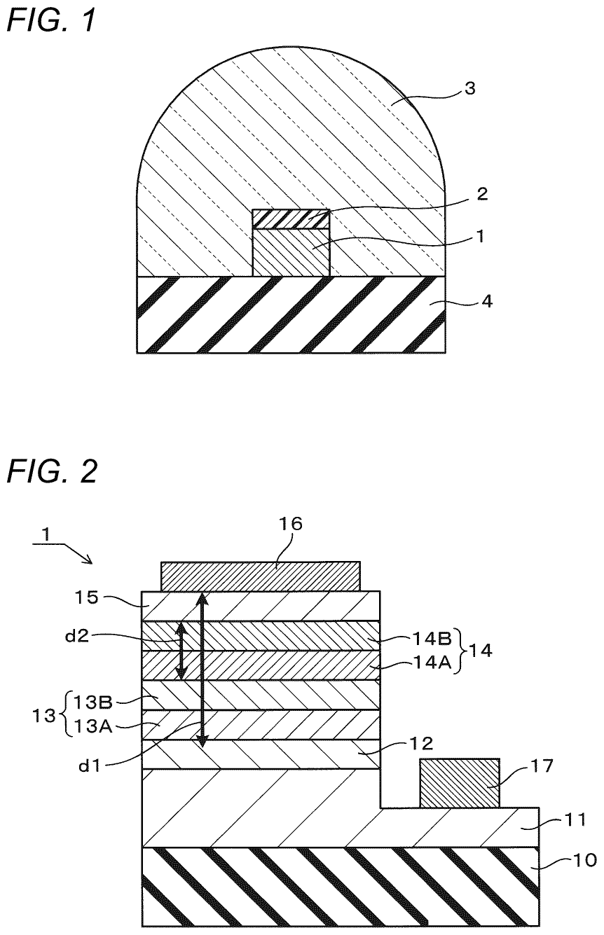

FIG. 1 is a cross-sectional view showing a configuration of a light emitting device according to an embodiment, and is a view showing a cross section in an axial direction. As shown in FIG. 1, the light emitting device according to a first embodiment includes a light emitting element 1, a sealing portion 2, a lens 3, and a mounting substrate 4.

The light emitting element 1 is a light emitting element using a Group III nitride semiconductor. The emission wavelength is, for example, 225 nm to 300 nm. A detailed configuration of the light emitting element 1 will be described later. The light emitting element 1 is a flip-chip type, with one surface serving as a light extraction side and the opposite surface serving as an electrode side. The light emitting element 1 is mounted on the mounting substrate 4. An upper surface is the main light extraction surface of the light emitting element 1, and light output from the upper surface is larger than light output from a side surface. Here, the upper surface of the light emitting element 1 is a surface opposite to a lower surface of the light emitting element 1, and the lower surface is a surface of the light emitting element 1 on the mounting substrate 4 side, that is, a surface on a side where the electrode is formed. The mounting substrate 4 is preferably made of a ceramic material having a high heat dissipation property such as AlN or SiC.

The sealing portion 2 is provided so as to fill a gap between the upper surface of the light emitting element 1 and the lens 3, and is provided in contact with the upper surface of the light emitting element 1 and the lens 3. The sealing portion 2 does not cover the side surface of the light emitting element 1. The sealing portion 2 preferably covers the entire upper surface of the light emitting element 1.

The refractive index of the sealing portion 2 is set to a value higher than the refractive index of air and lower than the refractive index of the light emitting element 1. Here, the refractive index is a value at the emission wavelength. The same applies to the following description unless otherwise specified. The refractive index of the light emitting element 1 is an average refractive index of the entire light emitting element 1. For example, the refractive index of the sealing portion 2 is 1.2 to 1.6.

If there is a gap between the upper surface of the light emitting element 1 and the lens 3 and an air layer is formed, a difference in refractive index between the light emitting element 1 and air is large, and the critical angle of total reflection at an interface between the upper surface of the light emitting element 1 and the air layer is small. As a result, the radiation angle of ultraviolet light that can be extracted from the light emitting element 1 is narrow, and a ratio of light incident on the lens 3 from the light emitting element 1 is low.

On the other hand, if the sealing portion 2 having the refractive index described above is provided between the upper surface of the light emitting element 1 and the lens 3, a difference in refractive index between the light emitting element 1 and the sealing portion 2 becomes small, so that the critical angle of total reflection at the interface between the upper surface of the light emitting element 1 and the sealing portion 2 becomes large. As a result, the radiation angle of ultraviolet light that can be extracted from the light emitting element 1 is widened, and the incidence efficiency of light from the light emitting element 1 to the lens 3 can be increased.

A material for the sealing portion 2 may be any material as long as the material is transparent to ultraviolet light emitted from the light emitting element 1, and may be liquid or solid. The material is preferably a material that is not deteriorated by the ultraviolet light emitted from the light emitting element 1. For example, an organic halide or a UVC transparent glass silicone resin may be used. As a liquid organic halide, silicone oil may be used. As a solid organic halide, fluororesins such as amorphous fluororesin, FEP, and PFA may be used.

As the material for the sealing portion 2, a fluorocarbon compound is particularly preferable. The fluorocarbon compound is a polymer with CF bonds. The fluorocarbon compound may be liquid (fluorine oil) at normal temperature and pressure, or may be solid. The number of carbon atoms in the fluorocarbon compound is preferably 1.9 times or less the number of fluorine atoms in the fluorocarbon compound. Examples of the fluorocarbon compound include perfluoropolyether (PFPE), polytetrafluoroethylene (PTFE), tetrafluoroethylene-hexafluoropropylene copolymer (PEP), tetrafluoroethylene-ethylene copolymer (ETFE), tetrafluoroethylene-perfluoroalkyl vinyl ether copolymer (PFA), and polychlorotrifluoroethylene (PCTFE).

The sealing portion 2 may be a fluororesin film. Alternatively, a liquid fluorocarbon compound may be sealed by being covered with a fluororesin film. Examples of the material for the fluororesin film include FEP, PFA, and PCTFE.

When the material for the sealing portion 2 is liquid, a filler may be mixed therein to adjust the viscosity. The filler is made of a material that does not absorb ultraviolet light, or the particle size thereof is adjusted so as not to absorb ultraviolet light. The material for the filler is, for example, fluororesin powder or silica. The refractive index of the filler is preferably about the same as the refractive index of the sealing portion 2, for example, 1.2 to 1.6.

A thickness and the refractive index of the sealing portion 2 may be set to values such that the sealing portion 2 functions as an antireflection film for preventing reflection between the light emitting element 1 and the lens 3. For example, the refractive index of the sealing portion 2 may be higher than the refractive index of the lens 3 and lower than the refractive index of the light emitting element 1, and the thickness of the sealing portion 2 may be set to ¼ of the emission wavelength. Therefore, the light extraction efficiency from the light emitting element 1 is further increased, and the axial intensity can be further increased.

The lens 3 is provided on the mounting substrate 4 so as to cover the side surface of the light emitting element 1 and the sealing portion 2. The lens 3 and the sealing portion 2 are in contact with each other. The side surface of the light emitting element 1 may be in contact with the lens 3, or an air layer may be provided between the side surface of the light emitting element 1 and the lens 3. By providing the air layer, total reflection on the side surface of the light emitting element 1 can be increased, and light extraction from the upper surface of the light emitting element 1 can be improved. The lens 3 and the mounting substrate 4 are bonded by an adhesive (not shown).

A surface of the lens 3 is spherical or parabolic. With the lens 3 having such a shape, light emitted from the upper surface of the light emitting element 1 is refracted in the axial direction and emitted from the lens 3. Therefore, the light intensity in the axial direction can be increased.

The material for the lens 3 may be any material as long as the material is transparent to ultraviolet light emitted from the light emitting element 1 and is not deteriorated by ultraviolet light. Examples of the material include quartz glass, glass, silicone, fluororesin, and transparent ceramics such as sapphire. The refractive index of the lens 3 is optional as long as it is larger than the refractive index of the sealing portion 2. For example, the refractive index of the lens 3 is 1.4 or more.

In the light emitting device according to the first embodiment, the sealing portion 2 is provided between the upper surface of the light emitting element 1 and the lens 3, so that the axial intensity can be improved. In particular, in consideration of the total reflection of the upper surface of the light emitting element 1 and the sealing portion 2, the configuration of the light emitting element 1 is devised so that the axial intensity of the light emitting device is increased. Hereinafter, the configuration of the light emitting element 1 will be described in detail.

### 2. Configuration of Light Emitting Element 1

FIG. 2 is a cross-sectional view showing the configuration of the light emitting element 1, and is a view showing a cross section in a direction perpendicular to the main surface of the substrate. As shown in FIG. 2, the light emitting element according to the embodiment includes a substrate 10, an n-type layer 11, an active layer 12, an electron blocking layer 13, a composition gradient layer 14, a p-type contact layer 15, a p-side electrode 16, and an n-side electrode 17. The light emitting element in the embodiment is of a flip-chip type and has an emission wavelength in the UVC band.

The substrate 10 is a substrate made of sapphire and having a c plane as a main surface. The main surface of sapphire may have an a plane orientation. Further, it may have an off angle of 0.1 to 2 degrees in an m-axial direction. A back surface (surface opposite to the n-type layer 11) of the substrate 10 is the main light extraction surface. An antireflection film may be provided on the back surface of the substrate 10 to improve the light extraction rate. Further, a surface of the substrate 10 may be provided with irregularities to improve the light extraction efficiency. As the substrate 10, an AlN substrate or an AlN template substrate in which an AlN layer is formed on a sapphire substrate may be used.

A thickness of the substrate 10 is, for example, 1000 μm or less. The thickness of the substrate 10 is preferably 500 μm or less. The extraction of light from the side surface of the substrate 10 can be suppressed, and the axial intensity can be improved.

The substrate 10 may be removed by a method such as LLO (laser lift off).

The n-type layer 11 is located on the substrate 10. The n-type layer 11 is made of n-AlGaN. The Al composition (molar ratio of Al in all Group III metals) is, for example, 60% to 90%. An n-type impurity is Si, and a Si concentration is, for example, 1×10¹⁸ cm⁻³ to 5×10¹⁹ cm⁻³. A thickness of the n-type layer 11 is, for example, 0.5 μm to 5 μm. A C concentration of the n-type layer 11 is 1×10¹⁵ cm⁻³ to 1×10¹⁹ cm⁻³. The n-type layer 11 may include a plurality of layers. For example, the n-type layer 11 may be a superlattice layer in which AlGaN having different Al compositions are alternately stacked. Further, a base layer made of AlN may be provided between the substrate 10 and the n-type layer 11. In addition, materials other than Si may be used as the n-type impurity.

The Al composition of the n-type layer 11 may be set to increase toward the substrate 10. Due to the refractive index distribution, the n-type layer 11 functions as a lens, and the axial intensity of the light emitting element 1 can be further increased.

The active layer 12 is located on the n-type layer 11. The active layer 12 has an SQW structure in which a barrier layer, a well layer, and a barrier layer are stacked in this order from the n-type layer 11 side. The active layer 12 may have an MQW structure. In this case, the number of repetitions is, for example, 2 to 10.

The well layer is made of AlGaN, and the Al composition thereof is set according to a desired emission wavelength. A Si concentration of the well layer is, for example, 1×10¹⁸ cm⁻³ or less, and may be non-doped. A thickness of the well layer is, for example, 0.5 nm to 5 nm.

The barrier layer is made of AlGaN having an Al composition higher than that of the well layer, and the Al composition is, for example, 50% to 100%. A Si concentration of the barrier layer is, for example, 2×10¹⁹ cm⁻³ or less, and may be non-doped. A thickness of the barrier layer is, for example, 3 nm to 30 nm. The barrier layer may be AlGaInN having band gap energy larger than that of the well layer. Among the barrier layers, the layer in contact with the electron blocking layer 13 preferably has a thickness of 0.5 nm to 10 nm.

A hole blocking layer may be provided between the n-type layer 11 and the active layer 12. Holes injected from the p-side electrode 16 can be prevented from going beyond the active layer 12 and diffusing toward the n-type layer 11 side. The hole blocking layer is AlGaN or AlN having an Al composition higher than that of the barrier layer of the active layer 12.

The electron blocking layer 13 is located on the active layer 12. The electron blocking layer 13 has a two-layer structure in which a first electron blocking layer 13A and a second electron blocking layer 13B are stacked in this order from the active layer 12 side. The electron blocking layer 13 prevents electrons injected from the n-side electrode 17 from going beyond the active layer 12 and diffusing toward the composition gradient layer 14.

The electron blocking layer 13 does not necessarily have a two-layer structure, and may have only the first electron blocking layer 13A.

The first electron blocking layer 13A is made of AlGaN or AlN having an Al composition ratio higher than that of the barrier layer of the active layer 12, and the Al composition is, for example, 90% to 100%. The first electron blocking layer 13A may be doped with a p-type impurity or may be non-doped. The p-type impurity is, for example, Mg. In the case of Mg-doped, a Mg concentration is, for example, 3×10²⁰ cm⁻³ or less. A thickness of the first electron blocking layer 13A is, for example, 1 nm to 10 nm.

The second electron blocking layer 13B is made of AlGaN having an Al composition lower than that of the first electron blocking layer 13A, and the Al composition is, for example, 80% to 99%. By providing the second electron blocking layer 13B, a difference in Al composition from the composition gradient layer 14 is adjusted. The resistance becomes high if only AlN is used as the first electron blocking layer 13A, and when the first electron blocking layer 13A is made thin, the performance of the electron blocking decreases. Therefore, the second electron blocking layer 13B is provided to achieve both low resistance and the electron blocking function. The second electron blocking layer 13B may be doped with a p-type impurity or may be non-doped. In the case of Mg-doped, a Mg concentration is, for example, 3×10²⁰ cm⁻³ or less. A thickness of the second electron blocking layer 13B is, for example, 1 nm to 10 nm.

The composition gradient layer 14 is located on the second electron blocking layer 13B. The composition gradient layer 14 has a two-layer structure in which a first composition gradient layer 14A and a second composition gradient layer 14B are stacked in this order from the electron blocking layer 13 side.

The composition gradient layer 14 is a p-type layer formed by a method called polarization doping. That is, the composition gradient layer 14 is a layer in which an Al composition changes in a thickness direction, and is set such that the Al composition decreases as a distance from the electron blocking layer 13 increases. It is difficult to increase a hole concentration in AlGaN having a high Al composition when doped with Mg, but the hole concentration can be improved by polarization doping, and the efficiency of hole injection into the active layer 12 can be increased. Since the polarization doping does not require doping with Mg, crystallinity can be improved.

When the Al composition of the composition gradient layer 14 is set as described above, polarization due to strain of the crystal occurs continuously in the thickness direction in the composition gradient layer 14. Holes are generated in the composition gradient layer 14 so as to cancel out fixed charges due to the polarization. The generated holes are distributed in the composition gradient layer 14. Therefore, the holes are widely distributed in the thickness direction from the electron blocking layer 13 side in the composition gradient layer 14, and the layer become a p type as a whole. In a p-type region, the hole concentration is 1×10¹⁶ cm⁻³ to 1×10²⁰ cm⁻³, and the hole concentration decreases as the distance from the electron blocking layer 13 increases. The reason why the number of holes decreases in the vicinity of an interface with the p-type contact layer 15 of the composition gradient layer 14 is that the band is bent as the Fermi levels try to match due to the p-type heterojunction.

The maximum value of the Al composition of the first composition gradient layer 14A (Al composition at the interface with the electron blocking layer 13) is preferably a value that is 1% to 20% lower than the Al composition of the electron blocking layer 13. The hole concentration can be further increased by polarization due to strain. For example, the maximum value of the Al composition is 65% to 95%.

The minimum value of the Al composition of the first composition gradient layer 14A (Al composition at the interface with the second composition gradient layer 14B) is preferably a value that is 3% to 30% lower than the maximum value of the Al composition of the first composition gradient layer 14A. The hole concentration can be further increased by polarization due to strain. In addition, an Al composition having band energy that does not absorb the emission wavelength is preferable.

A reduction rate of the Al composition is preferably 0.1%/nm to 0.3%/nm. In such a range, the hole concentration of the composition gradient layer 14 can be further increased. The reduction rate of the Al composition may be constant, that is, may change linearly, or may not be constant.

The first composition gradient layer 14A is non-doped. The first composition gradient layer 14A may be Mg-doped. Further improvement in hole concentration can be expected due to the p-type impurity. In this case, the Mg concentration is, for example, 1×10²⁰ cm⁻³ or less. On the other hand, from the viewpoint of suppressing a change in series resistance due to a change in the thickness of the first composition gradient layer 14A, the Mg concentration is preferably as low as possible, and non-doped is preferable.

The second composition gradient layer 14B is a layer having a Mg concentration higher than that of the first composition gradient layer 14A, and the Al composition is otherwise set similarly to the first composition gradient layer 14A. The second composition gradient layer 14B has an Al composition that changes in the thickness direction, and the Al composition is set to decrease as the distance from the electron blocking layer 13 increases. By doping the second composition gradient layer 14B with Mg, good connection to the p-type contact layer 15 is enabled.

The maximum value of the Al composition of the second composition gradient layer 14B (Al composition at the interface with the first composition gradient layer 14A) has a difference of 0% to 5% from the minimum value of the Al composition of the first composition gradient layer 14A, and is preferably the same as the minimum value of the Al composition of the first composition gradient layer 14A. That is, the Al composition is preferably continuous from the first composition gradient layer 14A to the second composition gradient layer 14B.

The minimum value of the Al composition of the second composition gradient layer 14B (Al composition at the interface with the p-type contact layer 15) is preferably a value that is 3% to 30% lower than the maximum value of the Al composition of the second composition gradient layer 14B.

A reduction rate of the Al composition of the second composition gradient layer 14B is in the same range as the reduction rate of the Al composition of the first composition gradient layer 14A. The reduction rate of the Al composition of the second composition gradient layer 14B may be the same as the reduction rate of the Al composition of the first composition gradient layer 14A.

The Mg concentration of the second composition gradient layer 14B is optional as long as it is higher than the Mg concentration of the first composition gradient layer 14A, and is preferably 3×10²⁰ cm⁻³ or less. This is to suppress the series resistance.

In the first embodiment, the Al composition of the composition gradient layer 14 is continuously decreased. Alternatively, the Al composition may be decreased stepwise. It is preferable that a region where the Al composition is constant is as small as possible.

A thickness of the composition gradient layer 14 is set to a thickness such that ultraviolet light emitted from the active layer 12 toward the n-type layer 11 and ultraviolet light emitted from the active layer 12 toward the electron blocking layer 13, reflected by the p-side electrode 16, and then directed toward the n-type layer 11 strengthen each other in the axial direction due to interference of light. Details thereof will be described later.

A ratio of the thickness of the first composition gradient layer 14A in the composition gradient layer 14 is preferably 0.4 to 0.7. In this range, the contact between the composition gradient layer 14 and the p-type contact layer 15 can be improved while sufficiently improving the hole concentration by polarization doping. More preferably, the ratio is 0.4 to 0.6.

The composition gradient layer 14 does not necessarily have a two-layer structure including the first composition gradient layer 14A and the second composition gradient layer 14B, and may have only the first composition gradient layer 14A. The composition gradient layer 14 may have a structure of three or more layers having different rates of change in Al composition, Mg concentrations, and the like.

A ratio of the thickness of the composition gradient layer 14 to a total film thickness of the electron blocking layer 13, the composition gradient layer 14, and the p-type contact layer 15 is preferably 50% or more and 90% or less. Within this range, the function of the p-type layer can be sufficiently enhanced.

The p-type contact layer 15 is located on the composition gradient layer 14. The p-type contact layer 15 is made of p-GaN. The p-type contact layer 15 may be made of p-AlGaN having an Al composition lower than the minimum Al composition of the composition gradient layer 14, and the Al composition is, for example, 50% or less. The p-type contact layer 15 may include a plurality of layers having different Al compositions or Mg concentrations. In order to reduce contact resistance, the uppermost layer in contact with the p-side electrode 16 is preferably p-GaN. GaN absorbs ultraviolet light emitted from the active layer 12, but can transmit ultraviolet light to some extent by making it sufficiently thin. Therefore, a large decrease in external quantum efficiency can be avoided. The Mg concentration of the p-type contact layer 15 is, for example, 1×10²⁰ cm⁻³ to 1×10²² cm⁻³. The thickness of the p-type contact layer 15 is, for example, 1 nm to 50 nm.

A groove having a depth reaching the n-type layer 11 is provided in a partial region of a surface of the p-type contact layer 15. This groove is for exposing the n-type layer 11 so that the n-side electrode 17 can be provided.

The p-side electrode 16 is provided on the p-type contact layer 15. The p-side electrode 16 is a reflective electrode that increases the light extraction efficiency by reflecting ultraviolet light emitted from the active layer 12 toward the substrate 10. A material for the p-side electrode 16 is Ru, Rh, Ni/Au, Ni/Al, ITO/Al, or the like. Here, A/B means that A and B are stacked in order from the p-type contact layer 15 side. The p-side electrode 16 may be a combination of a transparent electrode such as ITO or IZO and a dielectric multilayer film (DBR). When the transparent electrode is used, a reflective surface is not an interface between a semiconductor crystal and the electrode, but an interface between the transparent electrode and the reflective electrode. For example, in the case of ITO/Al, it is necessary to consider a film thickness of ITO as a film thickness for optical interference effects. However, since there is currently no electrode that is completely transparent to UVC light, it is most preferable to form a reflective electrode directly on the semiconductor crystal.

The n-side electrode 17 is provided on the n-type layer 11 exposed at a bottom surface of the groove. A material for the n-side electrode 17 is Ti/Al, V/Al, or the like. Here, A/B means that A and B are stacked in order from the n-type layer 11 side.

Next, the thickness of each layer in the light emitting element 1 will be described. First, thicknesses d1 to d3 are set as follows. A total film thickness from the uppermost barrier layer to the p-type contact layer 15 is defined as d1, the thickness of the composition gradient layer 14 is defined as d2, and a thickness obtained by subtracting d2 from d1 (a total thickness of the uppermost barrier layer of the active layer 12, the electron blocking layer 13, and the p-type contact layer 15) is defined as d3 (=d1-d2).

At this time, d1 is set to satisfy n×d1=m×λ. In the equation, n is the average refractive index of semiconductor layers from the uppermost barrier layer to the p-type contact layer 15, λ is the emission wavelength, and m is 0.5 to 0.9.

The equation is a conditional equation in which the ultraviolet light emitted from the active layer 12 toward the n-type layer 11 and the ultraviolet light emitted from the active layer 12 toward the electron blocking layer 13, reflected by the p-side electrode 16, and then directed toward the n-type layer 11 strengthen each other in the axial direction due to interference of light. Further, in this equation, in consideration of total reflection at an interface between the upper surface of the light emitting element 1 and the sealing portion 2, the range of m is set so that ultraviolet light whose radiation angle is less than the critical angle from the active layer 12 becomes stronger. When the thickness d1 is set to satisfy this equation, the axial intensity of the light emitting device can be improved.

Here, a necessary value for the thickness of the barrier layer of the active layer 12 is determined by a function called confinement of carriers. The necessary value for the thickness of the electron blocking layer 13 is determined by the function of blocking electrons. The thickness of the p-type contact layer 15 is determined to be a thickness having a predetermined value such that absorption of ultraviolet light is suppressed as much as possible while maintaining good contact with the p-side electrode 16. Further, when the thicknesses of the electron blocking layer 13 or the thicknesses of the p-type contact layer 15 is changed, the series resistance also changes, and a drive voltage of the light emitting element 1 also fluctuates.

Generally, a Mg activation rate of Mg-doped AlGaN is very low. Therefore, in the case of a film having a constant Al composition, since the resistance of the film is very high, the series resistance greatly affects the film thickness. On the other hand, the composition gradient layer 14 has a very low resistance due to the mechanism itself of being made p type by the polarization doping. Therefore, even if the thickness is changed, the influence of the series resistance on the increase in the drive voltage is small.

In the first embodiment, with only the thickness d2 of the composition gradient layer 14 in the thickness d1 as a parameter, and the other thickness d3 as a fixed value, d2 is set to satisfy n×d2=m×λ−n×d3. By controlling the interference of ultraviolet light by the thickness d2 of the composition gradient layer 14 in this way, it is possible to improve the axial intensity of the light emitting device while suppressing an increase in the drive voltage of the light emitting element 1.

In the composition gradient layer 14, it is preferable to change the thickness of the first composition gradient layer 14A, and set the thickness of the second composition gradient layer 14B to a fixed value, d2. This is because the second composition gradient layer 14B is Mg-doped, and a change in series resistance when the thickness of the second composition gradient layer 14B is changed is larger than when the thickness of the first composition gradient layer 14A is changed. At this time, the thickness of the second composition gradient layer 14B is preferably a fixed value in the range of 10 nm to 50 nm.

The transmittance and reflectance of each layer in the light emitting element 1 with respect to the emission wavelength are preferably set to satisfy the following. By setting the transmittance and the reflectance as described above, the absorption of light inside the light emitting element 1 can be suppressed, and the light extraction efficiency can be improved.

The transmittance of the substrate 10 which is an AlN template is preferably 50% or more. The overall transmittance (incident from the substrate side) from the substrate 10 to the p-type contact layer 15 is preferably 40% or more. The transmittance of the well layer alone in the active layer 12 is preferably 30% or more. The transmittance of the barrier layer alone in the active layer 12 is preferably 50% or more. The transmittance of the electron blocking layer 13 alone is preferably 50% or more. The transmittance of the composition gradient layer 14 alone is preferably 50% or more. The reflectance of the p-side electrode 16 is preferably 30% or more.

The transmittance and the reflectance depend on the material, the thickness, crystallinity, and the like, and the crystallinity depends on the growth conditions such as a growth temperature, a growth pressure, a V/III ratio, and a growth rate. Therefore, the transmittance and the reflectance are set according to these various conditions. Further, the transmittance and the reflectance are values at the emission wavelength, and are in the case of vertical incidence from the substrate 10 side. Further, the transmittance and the reflectance of each layer alone are evaluated using a sample in which a layer to be evaluated is formed on the substrate 10, which is an AlN template.

As described above, in the light emitting element 1, since the interference of ultraviolet light is controlled by the thickness d2 of the composition gradient layer 14, the change in the series resistance of the light emitting element 1 is small. As a result, the axial intensity of the light emitting device can be improved while suppressing an increase in the drive voltage of the light emitting element 1.

### 3. Experiment Results

Next, various experiment results regarding the light emitting device according to the first embodiment will be described.

### Experiment 1

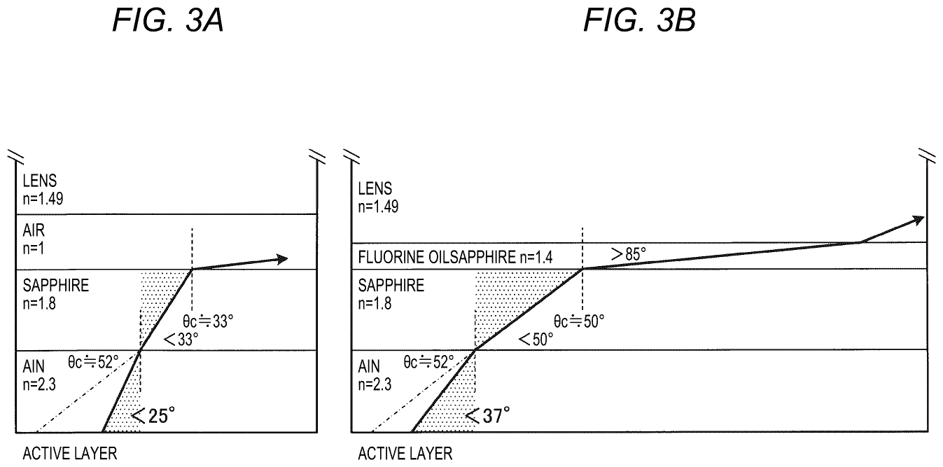

In the light emitting device according to the embodiment, ultraviolet light incident on the lens 3 from the light emitting element 1 was considered. FIGS. 3A and 3B are diagrams schematically showing paths of light inside simple models of the light emitting device. In FIG. 3A, AlN, sapphire, air, and a lens (quartz) are stacked on an active layer in this order from the active layer side. In FIG. 3B, AlN, sapphire, fluorine oil, and a lens (quartz) are stacked on an active layer in this order from the active layer side. The refractive index of each layer is 2.3 for AlN, 1.8 for sapphire, 1 for air, 1.4 for fluorine oil, and 1.49 for the lens.

In the case of FIG. 3A, in order to prevent ultraviolet light from the active layer 12 from being totally reflected at an interface between sapphire and air, a radiation angle of the ultraviolet light from the active layer 12 is necessarily less than 25°.

On the other hand, in the case of FIG. 3B, in order to prevent the ultraviolet light from the active layer 12 from being totally reflected at an interface between sapphire and fluorine oil, a radiation angle of the ultraviolet light from the active layer 12 is necessarily less than 37°.

From the results of FIGS. 3A and 3B, it was found that by filling a space between the back surface of the substrate 10 of the light emitting element 1 and the lens 3 with the sealing portion 2, a range of the radiation angle which allows extraction can be expanded, and the light extraction efficiency from the back surface of the substrate 10 can be improved. In order to increase the axial intensity of the light emitting device, it is necessary that ultraviolet light emitted from the active layer 12 at a radiation angle of less than 37° strengthens each other due to interference.

### Experiment 2

The light output of the light emitting element 1 was calculated using a simplified model, and conditions for making the light strengthen each other due to interference at a radiation angle of less than 37° were considered.

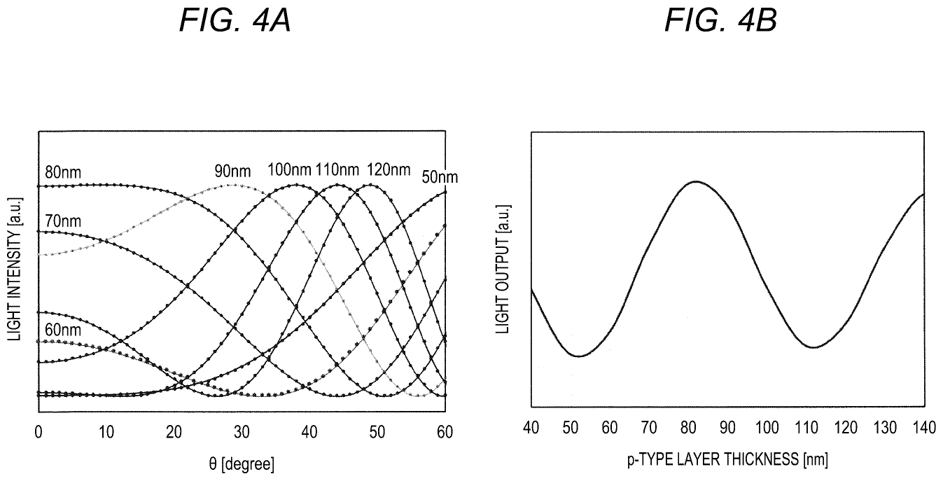

FIGS. 4A and 4B are graphs showing calculation results of light output. A model has a structure in which an n-type layer, an active layer, a p-type layer, and a reflective electrode are stacked on a substrate in this order from the substrate side, and a dependence of the light intensity on a radiation angle of the ultraviolet light from the active layer 12 due to optical interference at different optical film thicknesses was calculated. The optical film thickness of the p-type layer was changed from 50 nm to 110 nm at intervals of 10 nm. The emission wavelength was 275 nm. FIG. 4A is a graph showing the dependency of light intensity on a radiation angle of the ultraviolet light from the active layer 12 at each optical film thickness, and FIG. 4B is a graph showing the thickness dependency of the p-type layer (optical film thickness d1).

From FIG. 4A, it was found that the thickness of the p-type layer is required to be 60 nm to 100 nm in order to make the light strengthen each other due to interference at a radiation angle of less than 37°.

### Experiment 3

Light emitting elements 1 in which the thickness of the composition gradient layer 14 was set to various values were produced, and the light output thereof was measured. The light output was calculated. A layer structure of the light emitting element 1 is as follows in order from the p-side electrode 16 to the substrate 10. A thickness ratio of the first composition gradient layer 14A to the second composition gradient layer 14B was 1:1.
p-side electrode 16: Ni/Au, Ni thickness: 10 nm, Au thickness: 50 nm
p-type contact layer 15: Mg-doped GaN, thickness: 10 nm
second composition gradient layer 14B: Mg-doped AlGaN, Al composition: 75% to 72%
first composition gradient layer 14A: non-doped AlGaN, Al composition: 78% to 75%
second electron blocking layer 13B: Mg-doped AlGaN, Al composition: 97%, thickness: 8.8 nm
first electron blocking layer 13A: Mg-doped AlN, thickness: 8 nm
barrier layer of active layer 12: Si-doped AlGaN, Al composition: 68%, thickness: 2.5 nm
well layer of active layer 12: non-doped AlGaN, Al composition: 46%, thickness: 1.7 nm
barrier layer of active layer 12: Si-doped AlGaN, Al composition: 68%, thickness: 9.4 nm
hole blocking layer: non-doped AlN, thickness: 0.5 nm
well layer of SL layer: non-doped AlGaN, Al composition: 46%, thickness: 0.5 nm
barrier layer of SL layer: Si-doped AlGaN, Al composition: 68%, thickness: 50 nm
n-type layer 11: Si-doped AlGaN, Al composition: 73%, thickness: 35 nm
n-type layer 11: Si-doped AlGaN, Al composition: 73%, thickness: 150 nm
n contact layer: Si-doped AlGaN, Al composition: 73%, thickness: 1200 nm
re-growth layer: AlN containing Ga, Al composition: 98%, thickness: 200 nm
AlN template: Ga-doped AlN, thickness: 2900 nm
sapphire: thickness: 430 μm

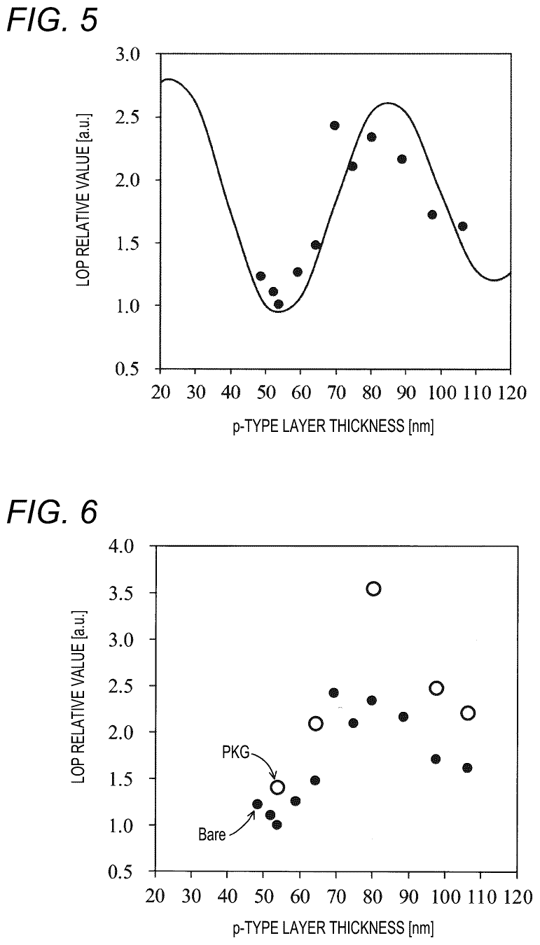

FIG. 5 is a graph showing calculation results of the light output of the manufactured light emitting element 1 (light emission area: about 550000 μm²) and measurement results when 350 mA is applied. The thickness of the p-type layer on the horizontal axis in FIG. 5 is the entire thickness from the uppermost barrier layers to the p-type contact layer 15. As shown in FIG. 5, it can be seen from the calculation result that the light output changes periodically by changing the thickness of the composition gradient layer 14, indicating that an interference effect occurs. The measurement results also confirmed that changing the thickness of the composition gradient layer 14 changes the light output due to interference. A drive voltage VF when 350 mA was applied was 6.15 V at the thinnest p-type layer thickness of 49 nm, and 6.35 V at the thickest p-type layer thickness of 107 nm, which was a difference of 0.2 V. The increase in VF due to the thickening of the p-type layer can be sufficiently suppressed.

### Experiment 4

FIG. 6 is a graph showing results of measuring light output of a light emitting device obtained by packaging the light emitting element 1 shown in FIG. 5 as in the embodiment. In FIG. 6, “Bare” indicates the light emitting element 1 alone, and “PKG” indicates the light emitting device. The p-type layer thickness on the horizontal axis is the same as in FIG. 5. As shown in FIG. 6, as the light output of the light emitting element 1 increases, the light output of the packaged light emitting device also increases.

### Experiment 5

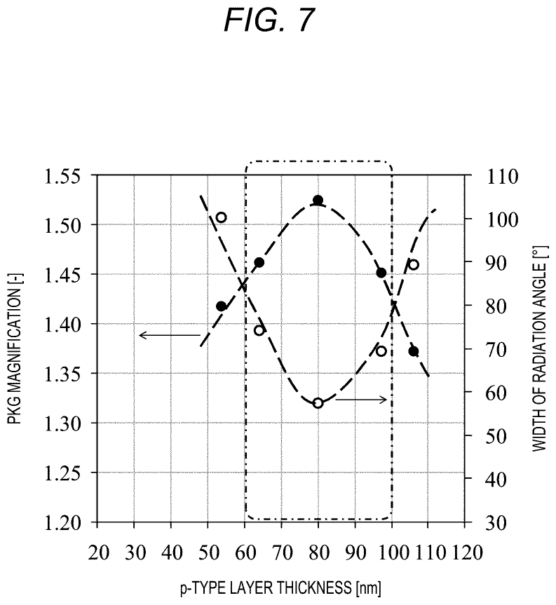

FIG. 7 is a graph showing measurement results of PKG magnification and a width of the radiation angle in a case where the light emitting element 1 shown in FIG. 5 is packaged to form the light emitting device as in the embodiment. The PKG magnification is a ratio of the light output of the light emitting device to the light output of the light emitting element 1 alone. The width of the radiation angle is a width of the radiation angle of the ultraviolet light from the light emitting device when the intensity of the ultraviolet light calculated from the far-field pattern is 0.8 times the maximum intensity. The p-type layer thickness on the horizontal axis is the same as in FIG. 5.

As shown in FIG. 7, it can be seen that when the width of the radiation angle is narrowed due to the packaging, the axial intensity also increases. It can be seen that when the axial intensity of the light emitting device is high, the PKG magnification is as high as 1.3 to 1.6. Accordingly, it can be seen that the width of the radiation angle is preferably 40° to 80°, and the thickness d1 is preferably 60 nm to 100 nm.

### Experiment 6

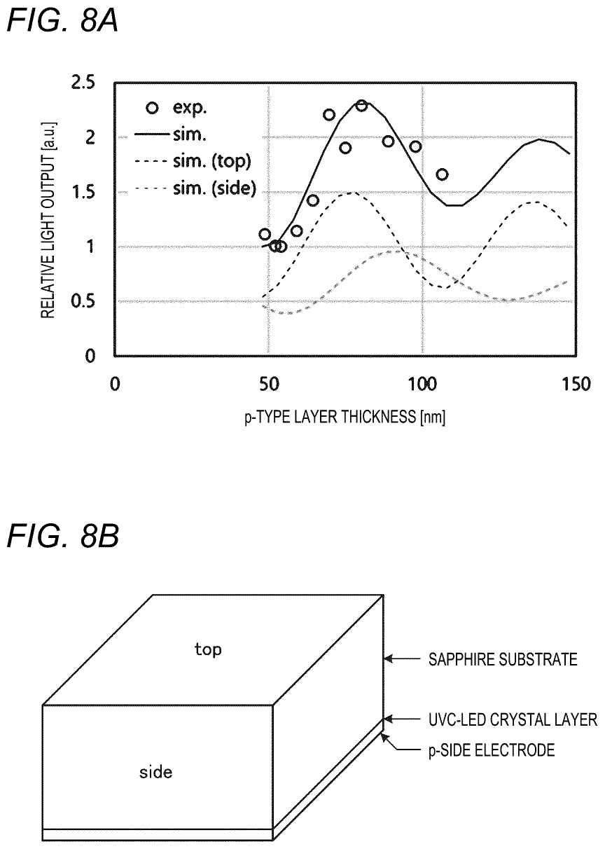

FIG. 8A is a graph showing results of calculating light output from an upper surface and light output from a side surface of the light emitting element 1 of Experiment 3. FIG. 8B is a schematic diagram of the light emitting element 1, showing the upper surface (top) and the side surface (side). The p-type layer thickness is the same as in FIG. 5. As shown in FIG. 8A, it can be seen that there is a difference in interference effect between the ultraviolet light extracted from the upper surface and the ultraviolet light extracted from the side surface of the light emitting element 1. Further, it can be seen that when the thickness of the p-type layer is in the range of 60 nm to 100 nm, the total light output is dominated by the light output from the upper surface.

### Experiment 7

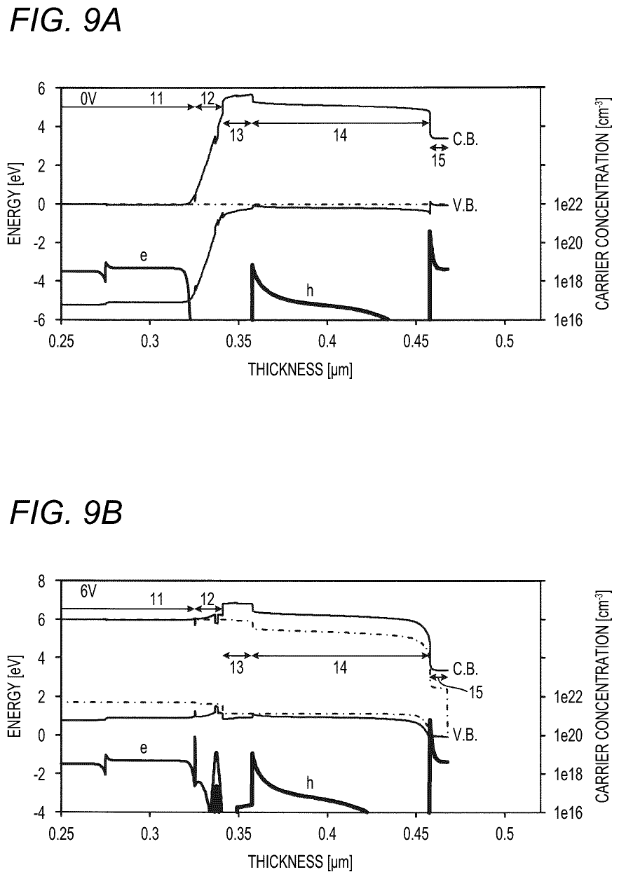

The band diagram and the carrier concentration of the light emitting element 1 were calculated. FIGS. 9A and 9B are diagrams showing the band diagram and carrier concentration distribution in the thickness direction of the light emitting element 1. FIG. 9A shows a case where no voltage is applied to the light emitting element 1, and FIG. 9B shows a case where 6 V is applied. In FIGS. 9A and 9B, a thin line indicates the band diagram, a medium line indicates a distribution of electron density, and a thick line indicates a distribution of the hole concentration. As shown in FIGS. 9A and 9B, it is confirmed that except for a region near the p-type contact layer 15 in the composition gradient layer 14, the hole concentration was 1×10¹⁶ cm⁻³ or more, and the layer was the p type due to polarization doping.

### Experiment 8

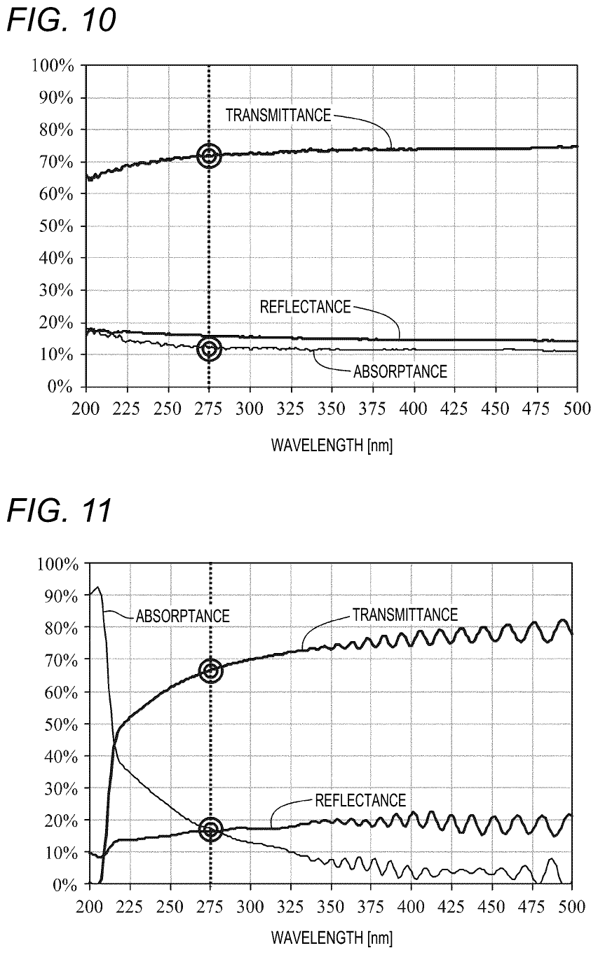

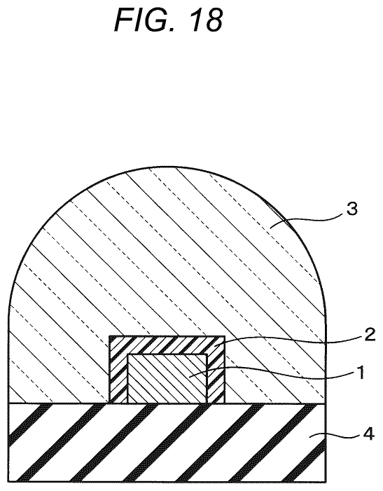

The transmittance and reflectance of each layer and the whole of the light emitting element 1 were measured, and the absorptance was calculated. FIGS. 10 to 17 are graphs showing the results. In FIGS. 13 to 16, these layers were formed on the substrate 10, which is an AlN template, and evaluated. In FIG. 17, the p-side electrode (Ni/Au) was formed on a sapphire substrate and evaluated. In FIGS. 10 to 16, evaluation was performed by allowing ultraviolet light to be vertically incident from the sapphire side. Although the sample has mirror surfaces on an incident surface, a transmission surface, and a reflection surface, it is considered that there is slight scattering. Therefore, the actual transmittance and reflectance are estimated to be slightly higher than the measured values. Accordingly, the following values roughly show optical characteristics of the film.

FIG. 10 is a graph regarding sapphire having a thickness of 430 μm, and FIG. 11 is a graph regarding a substrate that is an AlN template in which Ga-doped AlN with a thickness of 3000 nm is formed on sapphire with a thickness of 430 μm. From FIG. 10, the transmittance of sapphire was about 70% at an emission wavelength of 275 nm. From FIG. 11, the transmittance of the AlN template was about 67% at an emission wavelength of 275 nm. From the point of view of improving the light extraction efficiency from the light emitting element 1, it is considered preferable that the transmittance of sapphire at the emission wavelength is about 60% or more and the transmittance of the AlN template is about 50% or more. From the results shown in FIGS. 10 and 11, it was confirmed that this was satisfied. The higher the transmittance of the film, the better. The transmittance of a crystal layer can be improved by reducing crystal defects and impurities in areas other than band energy.

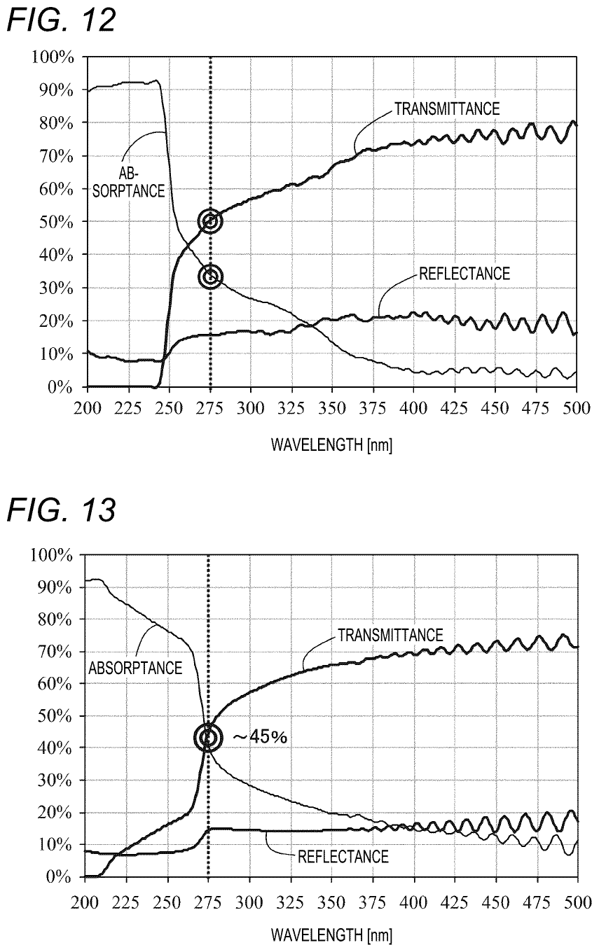

FIG. 12 is a graph regarding the entire structure from the substrate 10 to the p-type contact layer 15. The configuration of each layer is shown in Experiment 3. As shown in FIG. 12, at an emission wavelength of 275 nm, an overall transmittance from the substrate 10 to the p-type contact layer 15 was 50%. From the point of view of improving the light extraction efficiency from the light emitting element 1, it is considered preferable that the overall transmittance from the substrate 10 to the p-type contact layer 15 at the emission wavelength is preferably 40% or more. From the results shown in FIG. 12, it was confirmed that this was satisfied. Even higher transmittance can be expected by improving the crystal quality of a thicker AlN template or Si-doped AlGaN layer.

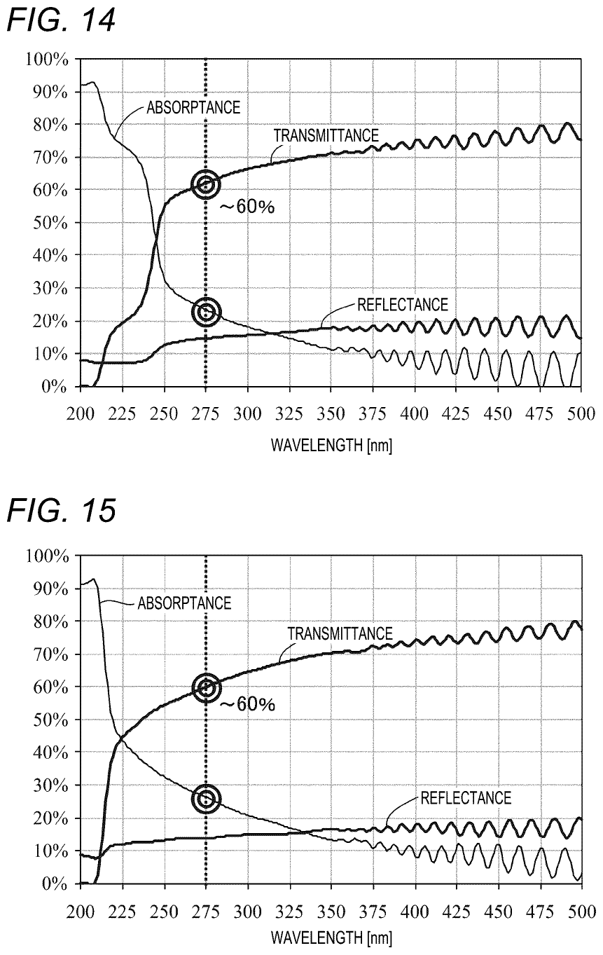

FIG. 13 is a graph regarding non-doped AlGaN (thickness: 68 nm, Al composition: 46%) of the well layer, FIG. 14 is a graph regarding Si-doped AlGaN (thickness: 52 nm, Al composition: 68%) of the barrier layer, and FIG. 15 is a graph regarding Mg-doped AlGaN (thickness: 70 nm, Al composition: 97%) of the electron blocking layer.

From FIG. 13, the transmittance of non-doped AlGaN was 45% at an emission wavelength of 275 nm. The AlGaN layer corresponds to the well layer. Since the film thickness of the well layer in an actual light emitting element is 1.7 nm, the self-absorption of light emitted from the light emitting layer in the well layer is considered to be low, and the transmittance is higher than 45%. In view of the above, the transmittance of the AlGaN layer with a thickness of 68 nm and an Al composition of 46% is preferably 45% or more.

From FIG. 14, the transmittance of Si-doped AlGaN was 60% at an emission wavelength of 275 nm. This layer corresponds to the barrier layer and is thicker than a film thickness of 10 nm in an actual light emitting element. Accordingly, the transmittance of the barrier layer in the light emitting element structure is higher than 40%, and the transparency is high. In view of the above, the transmittance of the AlGaN layer with a thickness of 52 nm and an Al composition of 68% is preferably 60% or more.

From FIG. 15, the transmittance of Mg-doped AlGaN was 60% at an emission wavelength of 275 nm. The AlGaN layer having band energy higher than the emission wavelength has a sufficient transmittance even if it is thicker than the actual film thickness of the light emitting element. From the point of view of improving the light extraction efficiency from the light emitting element 1, it is considered preferable that the transmittance of the electron blocking layer 13 at the emission wavelength is 60% or more. From the results shown in FIG. 15, it was confirmed that this was satisfied.

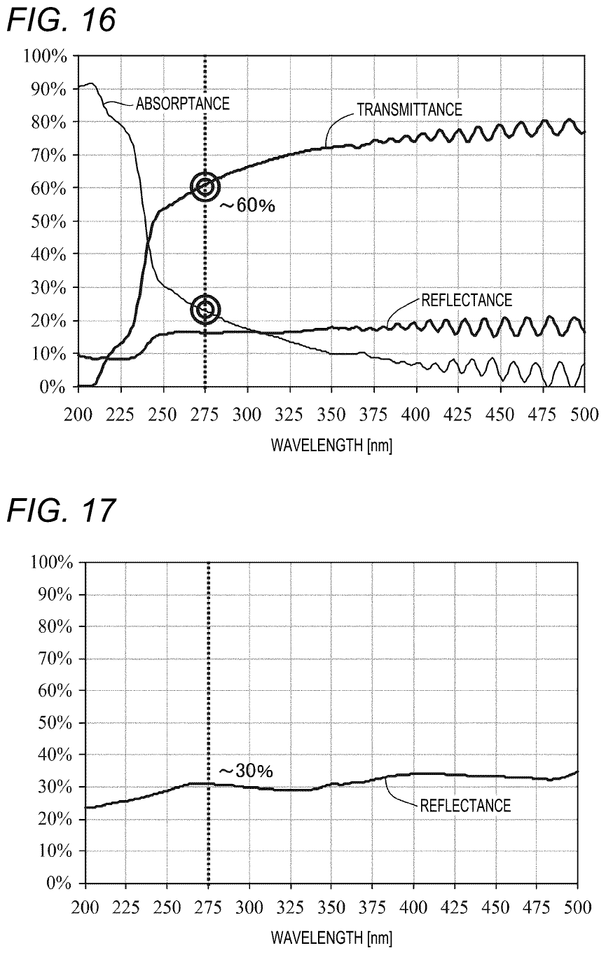

FIG. 16 is a graph regarding the composition gradient layer 14 (thickness: 107 nm). The composition gradient layer 14 includes the first composition gradient layer 14A made of non-doped AlGaN with an Al composition decreased from 78% to 75%, and the second composition gradient layer 14B made of Mg-doped AlGaN with an Al composition decreased from 75% to 73%.

From FIG. 16, the transmittance of the composition gradient layer 14 was 60% at an emission wavelength of 275 nm.

From the point of view of improving the light extraction efficiency from the light emitting element 1, it is considered preferable that the transmittance of the composition gradient layer 14 at the emission wavelength is 50% or more. From the results shown in FIG. 16, it was confirmed that this was satisfied.

FIG. 17 is a graph regarding the p-side electrode 16. The p-side electrode 16 was made of Ni/Au, with a Ni thickness of 10 nm and an Au thickness of 50 nm. Further, evaluation was performed by vertical incidence from the Ni side. From FIG. 17, the reflectance was 30% or more at an emission wavelength of 275 nm. From the point of view of improving the light extraction efficiency from the light emitting element 1, it is considered preferable that the reflectance of the p-side electrode 16 at the emission wavelength is 30% or more. From the results shown in FIG. 17, it was confirmed that this was satisfied.

### Modifications

In the embodiment, the sealing portion 2 covers only the upper surface of the light emitting element 1. As shown in FIG. 18, the side surface of the light emitting element 1 may be covered in addition to the upper surface. By providing the sealing portion 2 on the side surface of the light emitting element 1, the light extraction efficiency from the side surface of the light emitting element 1 can be improved. The ultraviolet light extracted from the side surface can be utilized, for example, by being reflected in the axial direction by a reflective material. When the material for the sealing portion 2 is liquid and has low viscosity, a partition wall may be provided around the light emitting element 1, and a region surrounded by the partition wall may be filled with the sealing portion 2.

What is claimed is:

1. A light emitting device comprising:
a flip-chip type light emitting element configured to emit ultraviolet light;
a sealing portion in contact with and covering at least an upper surface of the light emitting element and having a refractive index higher than a refractive index of air and lower than a refractive index of the light emitting element; and
a lens in contact with and covering the sealing portion and having a refractive index higher than the refractive index of the sealing portion,
wherein the light emitting element comprises
an n-type layer comprising an n-type group III nitride semiconductor containing Al,
an active layer located at a main surface of the n-type layer at a side opposite to the sealing portion, comprising a group III nitride semiconductor containing Al, and having a quantum well structure including a well layer and a barrier layer,
an electron blocking layer located at a main surface of the active layer at a side opposite to the n-type layer, comprising a p-type group III nitride semiconductor containing Al, and having an Al composition higher than an Al composition of the barrier layer,
a composition gradient layer located at a main surface of the electron blocking layer at a side opposite to the active layer, comprising a p-type group III nitride semiconductor containing Al, and having an Al composition which decreases as a distance from the active layer increases,
a p-type contact layer located at a main surface of the composition gradient layer at a side opposite to the electron blocking layer, and comprising a p-type group III nitride semiconductor containing Al, and
a p-side electrode located at a main surface of the p-type contact layer at a side opposite to the composition gradient layer, and configured to reflect ultraviolet light from the active layer, and
wherein a thickness of the composition gradient layer is set such that light directed from the active layer toward the n-type layer and light directed from the active layer toward a side opposite to the n-type layer and then reflected by the p-side electrode toward the n-type layer strengthen each other in a direction perpendicular to a main surface of the light emitting element due to interference.

2. The light emitting device according to claim 1,
wherein when a total thickness from an uppermost layer of the barrier layer to the p-type contact layer is d1, and the thickness of the composition gradient layer is d2, the thickness d2 is set such that the total thickness d1 satisfies n×d1=m×λ, wherein n is an average refractive index of layers from the electron blocking layer to the p-type contact layer at an emission wavelength, λ is the emission wavelength, and m is 0.55 or more and 0.9 or less.

3. The light emitting device according to claim 1,
wherein the composition gradient layer has a structure in which a first composition gradient layer and a second composition gradient layer are stacked in order from a side of the electron blocking layer, the first composition gradient layer is non-doped or doped with p-type impurities, and the second composition gradient layer is doped with p-type impurities and has a p-type impurity concentration higher than the first composition gradient layer.

4. The light emitting device according to claim 2,
wherein the composition gradient layer has a structure in which a first composition gradient layer and a second composition gradient layer are stacked in order from a side of the electron blocking layer, the first composition gradient layer is non-doped or doped with p-type impurities, and the second composition gradient layer is doped with p-type impurities and has a p-type impurity concentration higher than the first composition gradient layer.

5. The light emitting device according to claim 3,
wherein the thickness of the composition gradient layer is set by a thickness of the first composition gradient layer.

6. The light emitting device according to claim 4,
wherein the thickness of the composition gradient layer is set by a thickness of the first composition gradient layer.

7. The light emitting device according to claim 3,
wherein a ratio of a thickness of the first composition gradient layer to the thickness d2 of the composition gradient layer is 0.4 to 0.7.

8. The light emitting device according to claim 4,
wherein a ratio of a thickness of the first composition gradient layer to the thickness d2 of the composition gradient layer is 0.4 to 0.7.

9. The light emitting device according to claim 1,
wherein the sealing portion is provided at the upper surface of the light emitting element and is not provided at a side surface of the light emitting element.

10. The light emitting device according to claim 2,
wherein the sealing portion is provided at the upper surface of the light emitting element and is not provided at a side surface of the light emitting element.

11. The light emitting device according to claim 1,
wherein the electron blocking layer has a structure in which a first electron blocking layer and a second electron blocking layer are stacked in order from a side of the active layer, and an Al composition of the second electron blocking layer is lower than an Al composition of the first electron blocking layer and lower than a maximum value of the Al composition of the composition gradient layer.

12. The light emitting device according to claim 2,
wherein the electron blocking layer has a structure in which a first electron blocking layer and a second electron blocking layer are stacked in order from a side of the active layer, and an Al composition of the second electron blocking layer is lower than an Al composition of the first electron blocking layer and lower than a maximum value of the Al composition of the composition gradient layer.

13. A manufacturing method for a light emitting device,
the light emitting device including
a flip-chip type light emitting element configured to emit ultraviolet light,
a sealing portion in contact with and covering at least an upper surface of the light emitting element and having a refractive index higher than a refractive index of air and lower than a refractive index of the light emitting element, and
a lens in contact with and covering the sealing portion and having a refractive index higher than the refractive index of the sealing portion,
the light emitting element including
an n-type layer comprising an n-type group III nitride semiconductor containing Al,
an active layer located at a main surface of the n-type layer at a side opposite to the sealing portion, comprising a group III nitride semiconductor containing Al, and having a quantum well structure including a well layer and a barrier layer,
an electron blocking layer located oat a main surface of the active layer at a side opposite to the n-type layer, comprising an p-type group III nitride semiconductor containing Al, and having an Al composition higher than an Al composition of the barrier layer,
a composition gradient layer located at a main surface of the electron blocking layer at a side opposite to the active layer, comprising a p-type group III nitride semiconductor containing Al, and having an Al composition which decreases as a distance from the active layer increases,
a p-type contact layer located at a main surface of the composition gradient layer at a side opposite to the electron blocking layer, and comprising a p-type group III nitride semiconductor containing Al, and
a p-side electrode located at a main surface of the p-type contact layer at a side opposite to the composition gradient layer, and configured to reflect ultraviolet light from the active layer,
the manufacturing method comprising:
setting a thickness of the composition gradient layer such that light directed from the active layer toward the n-type layer and light directed from the active layer toward a side opposite to the n-type layer and then reflected by the p-side electrode toward the n-type layer strengthen each other in a direction perpendicular to a main surface of the light emitting element due to interference.

14. The manufacturing method for a light emitting device according to claim 13,
wherein when a total thickness from an uppermost layer of the barrier layer to the p-type contact layer is d1, the thickness of the composition gradient layer is d2, and d3=d1−d2, by changing the thickness d2 while fixing the thickness d3 to a predetermined value, the thickness d2 is set such that n×d1=m×λ, in which n is an average refractive index of layers from the electron blocking layer to the p-type contact layer at an emission wavelength, and A is the emission wavelength, is satisfied, m being 0.55 or more and 0.9 or less.

15. The manufacturing method for a light emitting device according to claim 13,
wherein the composition gradient layer has a structure in which a first composition gradient layer and a second composition gradient layer are stacked in order from a side of the electron blocking layer, the first composition gradient layer is non-doped or doped with p-type impurities, and the second composition gradient layer is doped with p-type impurities and has a p-type impurity concentration higher than the first composition gradient layer, and
wherein the thickness of the composition gradient layer is set by fixing a thickness of the second composition gradient layer to a predetermined value and changing a thickness of the first composition gradient layer.

16. The manufacturing method for a light emitting device according to claim 14,
wherein the composition gradient layer has a structure in which a first composition gradient layer and a second composition gradient layer are stacked in order from a side of the electron blocking layer, the first composition gradient layer is non-doped or doped with p-type impurities, and the second composition gradient layer is doped with p-type impurities and has a p-type impurity concentration higher than the first composition gradient layer, and
wherein the thickness of the composition gradient layer is set by fixing a thickness of the second composition gradient layer to a predetermined value and changing a thickness of the first composition gradient layer.
